(19) United States
(12) Patent Application Publication
(10) Pub. No.: US 2024/0196761 A1
(43) Pub. Date: Jun. 13, 2024

(54) VAN DER WAALS STACKED JOSEPHSON JUNCTION STRUCTURE AND METHOD FOR FABRICATING SAME

(71) Applicant: POSTECH Research and Business Development Foundation, Pohang-si (KR)

(72) Inventors: Gil Ho LEE, Pohang-si (KR); Jong Yun LEE, Pohang-si (KR)

(73) Assignee: POSTECH Research and Business Development Foundation, Pohang-si (KR)

(21) Appl. No.: 18/533,756

(22) Filed: Dec. 8, 2023

(30) Foreign Application Priority Data
Dec. 9, 2022 (KR) 10-2022-0171668

(51) Int. Cl. H10N 60/80; H10N 60/01; H10N 60/12

(52) U.S. Cl. CPC H10N 60/805; H10N 60/0912; H10N 60/12

(57) ABSTRACT

A van der Waals stacked Josephson junction structure and a method for fabricating the same are provided. The van der Waals stacked Josephson junction structure according to an embodiment of the present disclosure includes a substrate, a first layer of a van der Waals material separable into layers and positioned on the substrate, and a second layer of the van der Waals material positioned on the first layer, in which the first layer and the second layer are twisted at a predetermined angle with each other, and a Josephson junction is formed between the first layer and the second layer.

### CROSS-REFERENCE TO RELATED APPLICATION

This application claims the benefit under 35 USC § 119(a) of Korean Patent Application No. 10-2022-0171668, filed on Dec. 9, 2022, in the Korean Intellectual Property Office, the entire disclosure of which is incorporated herein by reference for all purposes.

### BACKGROUND

### 1. Field

Embodiments of the present disclosure relate to a van der Waals stacked Josephson junction structure and a method for fabricating the same.

### 2. Description of Related Art

Van der Waals materials offer a variety of electron transport properties in two-dimensional (2D) systems, including metals, superconductors, insulators, semiconductors, and topological materials. It has become possible to design and engineer material properties by stacking two-dimensional van der Waals structures. The recent stacking of van der Waals materials having a twist angle provides an exciting platform for twistronics, while providing opportunities to study various physical phenomena. One good example is twisted bilayer graphene, which exhibits related physics phenomena leading to the Mott insulator phase, superconductivity, and ferromagnetism.

A Josephson junction refers to a state where supercurrent flows due to the quantum tunnel effect or proximity effect when a different material is intervened between superconductors, and is mainly used in quantum devices such as a superconducting quantum interference device (SQUID) and superconducting qubit. Josephson junction devices are generally fabricated through processes such as lithography and metal deposition. During these processes, physical and chemical damage and deformation occur on a junction surface, which causes a problem of damage to the fabricated device.

### PRIOR ART LITERATURE

### Patent Literature

PTL 1: US Patent Publication No. US2021/0242391 (2021 Sep. 5)

### SUMMARY

An embodiment of the present disclosure is to provide a van der Waals stacked Josephson junction structure and a method for fabricating the same, which do not require processes such as lithography and metal deposition for forming the Josephson junction.

In addition, an embodiment of the present disclosure is to provide a van der Waals stacked Josephson junction structure and a method for fabricating the same, which can control the Josephson junction characteristics through angle control between two layers produced from one van der Waals material.

In addition, an embodiment of the present disclosure is to provide a method for fabricating a van der Waals stacked Josephson junction structure using a method of separating a material that was originally one body to be layered in order to control an angle between two layers.

In addition, an embodiment of the present disclosure is to provide a Josephson junction structure and a method for fabricating the same, which can prevent mechanical and chemical defects occurring during the fabrication process.

According to an embodiment of the present disclosure, there is provided a Josephson junction structure including a substrate, a first layer of a van der Waals material separable into layers and positioned on the substrate, and a second layer of the van der Waals material positioned on the first layer, in which the first layer and the second layer are twisted at a predetermined angle with each other, and a Josephson junction is formed between the first layer and the second layer.

Each of the first layer and the second layer may include a superconducting layer.

A crystal structure of the first layer and a crystal structure of the second layer may be twisted at the predetermined angle.

The van der Waals material may be a superconductor selected from Bi-2212, NbSe₂, FeSe, and FeTe.

Each of the first layer and the second layer may include CuO₂.

Further, according to another embodiment of the present disclosure, there is provided a method for fabricating a Josephson junction structure including disposing a Van der Waals material separable into layers on a substrate, separating the van der Waals material into a first layer remaining on the substrate and a second layer separated from the first layer using a separation tool, twisting the first layer and the second layer at a predetermined angle with each other, and stacking the second layer on the first layer in a a state of being twisted at the predetermined angle.

The substrate may be rotated in order to twist the first layer and the second layer at the predetermined angle.

Each of the first layer and the second layer may include a superconducting layer.

A crystal structure of the first layer and a crystal structure of the second layer may be twisted at the predetermined angle.

The van der Waals material may be a superconductor selected from Bi-2212, NbSe₂, FeSe, and FeTe.

Each of the first layer and the second layer may include CuO₂.

According to an embodiment of the present disclosure, there is provided a van der Waals stacked Josephson junction structure and a method for fabricating the same, which do not require processes such as lithography and metal deposition for forming the Josephson junction.

In addition, according to an embodiment of the present disclosure, there is provided a van der Waals stacked Josephson junction structure and a method for fabricating the same, which can control the Josephson junction characteristics through angle control between two layers produced from one van der Waals material.

In addition, according to an embodiment of the present disclosure, there is provide a Josephson junction structure and a method for fabricating the same a Josephson junction structure and a method for fabricating the same, which can prevent mechanical and chemical defects occurring during the fabrication process.

### BRIEF DESCRIPTION OF THE DRAWINGS

FIG. 1 is a view illustrating an example of a van der Waals material.

FIGS. 2 to 7 are views illustrating a process of fabricating a Josephson junction structure according to an embodiment of the present disclosure.

FIG. 2 is a view illustrating disposing the van der Waals material on a substrate.

FIG. 3 is a view illustrating separating the van der Waals material into a first layer and a second layer using a separation tool.

FIG. 4 is a view illustrating twisting the separated first layer and second layer at a predetermined angle with each other.

FIG. 5 is a view illustrating stacking the second layer on the first layer.

FIG. 6 is a view illustrating a state in which the separation tool is removed.

FIG. 7 is a view illustrating an example of a device including the Josephson junction structure according to an embodiment of the present disclosure.

### DETAILED DESCRIPTION

Hereinafter, specific embodiments of the present disclosure will be described with reference to the drawings. The following description is provided to assist the reader in gaining a comprehensive understanding of the methods, apparatuses, and/or systems described herein. However, this is only an example and disclosed embodiments are not limited thereto.

In describing the embodiments, when it is determined that a detailed description of related known technologies may unnecessarily obscure the gist of the disclosed embodiments, the detailed description thereof will be omitted. Also, terms described in below are selected by considering functions in the embodiments and meanings may vary depending on, for example, a user or operator's intentions or customs. Therefore, definitions of the terms should be made on the basis of the contents throughout this specification. The terms used in the detailed description are provided only to describe embodiments and should never be used in a limiting sense. Unless the context clearly indicates otherwise, the singular forms include the plural forms. It should be understood that the terms “comprises” or “includes” specify some features, numbers, steps, operations, elements, and/or combinations thereof when used herein, but do not preclude the presence or possibility of one or more other features, numbers, steps, operations, elements, and/or combinations thereof in addition to those described.

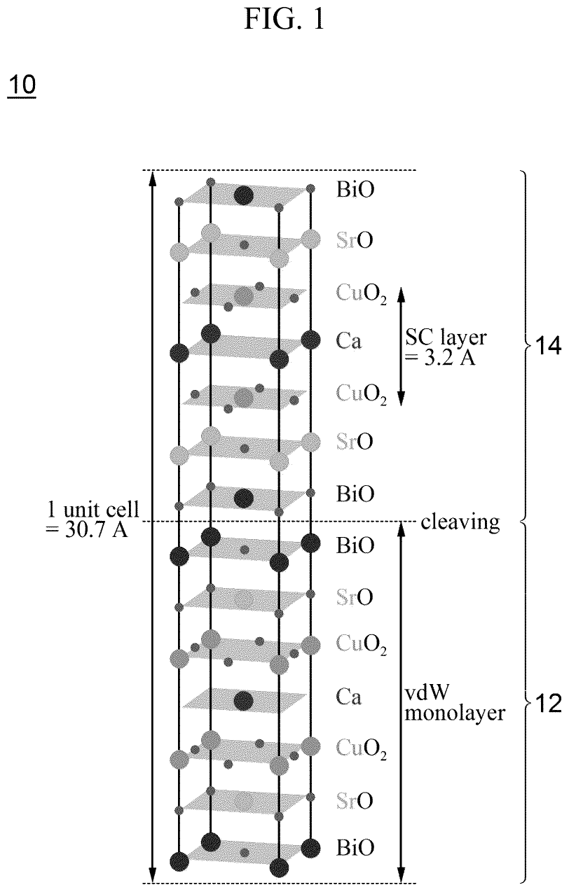

FIG. 1 is a view illustrating an example of a van der Waals material.

Referring to FIG. 1, the van der Waals material may be a two-dimensional material capable of being separated into upper and lower layers. The material illustrated in FIG. 1 is Bi-2212 (Bi₂Sr₂CaCu₂O₈₊ₓ), and may have a stacked structure in which a superconducting CuO₂ bilayer and an insulating SrO—BiO layer are alternately stacked. A height of a single unit cell may be 30.7 Å, and a height of each of two superconducting CuO₂ layers included in the single unit cell may be 3.2 Å. A single unit cell 10 may be divided into a first layer 12 and a second layer 14, and element arrangements of the first layer 12 and the second layer 14 may be the same. However, the element arrangements between the first layer 12 and the second layer 14 do not necessarily have to be the same.

Bi-2212 (Bi₂Sr₂CaCu₂O₈₊ₓ) is a mechanically cleavable van der Waals high critical temperature superconductor (HTSC). Bi-2212 has a stacked structure in which the superconducting CuO₂ bilayer and the insulating SrO—BiO layer are alternately stacked. The insulating SrO—BiO layer acts as a tunnel barrier to thereby form a tunnel-like Josephson junction between two superconducting CuO₂ bilayers along the c-axis of the crystal, which is called intrinsic Josephson coupling. Unlike other superconducting materials, Bi-2212 can form a tunneling junction along the c-axis without the insertion of an insulating layer. The reason for this is that a termination layer is an insulating BiO layer because mechanical cleavage occurs between the BiO bilayers due to weak van der Waals bonds.

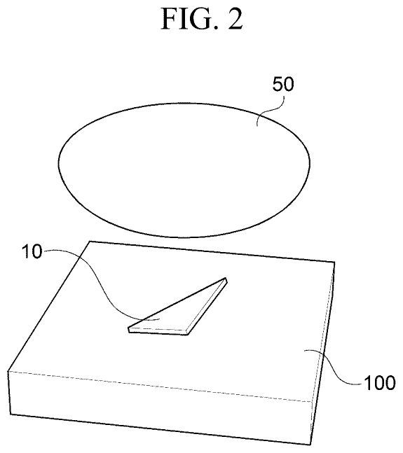

FIGS. 2 to 7 are views illustrating a process of fabricating a Josephson junction structure according to an embodiment of the present disclosure.

FIG. 2 is a view illustrating disposing a Van der Waals material on a substrate 100.

Referring to FIG. 2, the substrate 100 may be undoped silicon (Si), or may also be a non-conductor such as silicon dioxide (SiO₂). First, the van der Waals material 10, for example, Bi-2212, may be disposed on the substrate 100. These steps may be performed in an argon (Ar) atmosphere in order to minimize structural and chemically generated defects at the van der Waals interface.

In order to increase a success rate of fine separation between the van der Waals materials 10, it may be necessary to increase the van der Waals forces between the substrate 100 and the van der Waals materials 10. To this end, the van der Waals forces between the substrate 10 and the van der Waals material 10 may be increased by treating the substrate 10 with oxygen plasma.

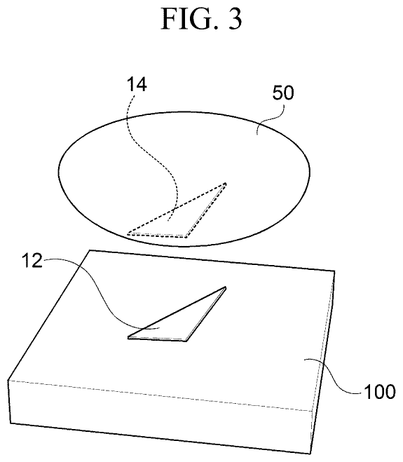

FIG. 3 is a view illustrating separating the van der Waals material into the first layer 12 and the second layer 14 using a separation tool 50.

Referring to FIG. 3, the separation tool 50 may be manufactured using a polymer in order to increase adhesion with the van der Waals material 10. In particular, the separation tool 50 may be made of a thermoplastic methacrylate copolymer. This separation process may be referred to as microcleaving and may be performed at 100 to 120° C. The corresponding temperature may be a temperature at which adhesion between the separation tool 50 and the van der Waals material 10 can be maximized within a range in which deformation of the separation tool 50 does not occur.

By this microcleaving process, the first layer 12, which is the lower layer of the van der Waals material 10, remains on the substrate 100, and the second layer 14, which is the upper layer, can be separated while being adhered to a lower portion of the separation tool 50.

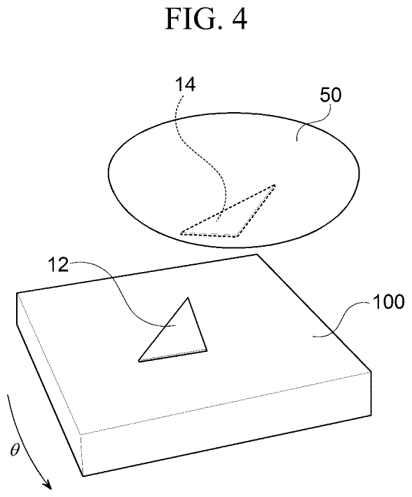

FIG. 4 is a view illustrating twisting the first layer and the second layer at a predetermined angle with each other.

Referring to FIG. 4, the first layer 12 positioned on the substrate 100 and the second layer 14 adhered to the lower portion of the separation tool 50 may be twisted at a predetermined angle θ. Through this, the first layer 12 and the second layer 14 having the same element arrangement and crystal structure may be in a state of being dislocated from each other by the predetermined angle θ. In order to twist the first layer 12 and the second layer 14, the substrate 100 may be rotated by the predetermined angle θ while maintaining the separation tool 50 as it is. Rotating the substrate 100 in this way may be rotating the first layer 12 on the substrate 100 which is stably positioned in order to prevent defects from occurring because mechanical and chemical defects may occur in the second layer 14 when the separation tool 50 is rotated.

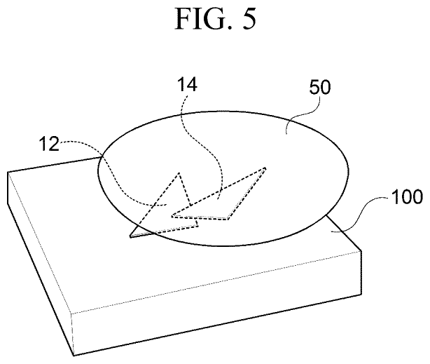

FIG. 5 is a view illustrating stacking the second layer 14 on the first layer 12.

Referring to FIG. 5, the second layer 14 attached to the lower side of the separation tool 50 may be stacked again on the first layer 12 on the substrate 100 with the separation tool 50 facing downward while maintaining the first layer 12 and the second layer 14 in a state of being twisted by the predetermined angle θ.

If time passes excessively, there is a concern that defects may occur in the first layer 12 and the second layer 14, which are separated layers of the van der Waals material, and thus the microcleaving process in FIG. 3 to this stacking process can be performed within 10 minutes.

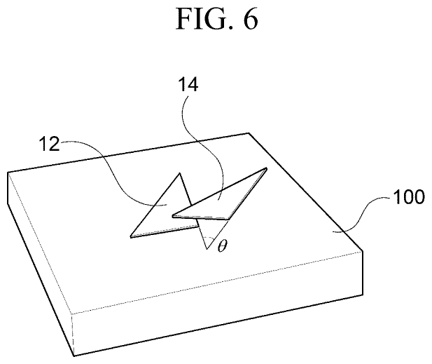

FIG. 6 is a view illustrating a state in which the separation tool 50 is removed.

Referring to FIG. 6, the separation tool 50 of polymer material may be removed from the second layer 14. To this end, the separation tool 50 can be removed by performing the process at 200° C. or higher, which is a temperature at which the polymer can be melted. In addition, washing with a cleaning agent such as acetone may be added in order to remove any polymer that may remain.

When the removal of the separation tool 50 is completed, the stacked body of the first layer 12 and the second layer 14 may be annealed to complete the fabrication of the Josephson junction structure. Annealing may be performed at 300 to 400° C.

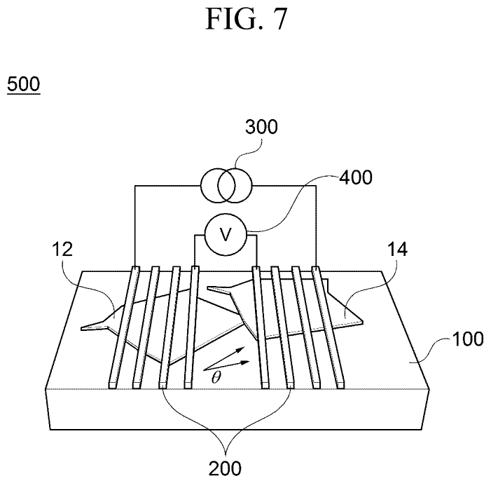

FIG. 7 is a view illustrating an example of a device including the Josephson junction structure according to an embodiment of the present disclosure.

Referring to FIG. 7, an electrode 200 may be formed on the Josephson junction structure formed by the first layer 12 and the second layer 14 twisted by the predetermined angle θ on the substrate 100 to be used as a device 500. The electrode 200 may be an Ag/Au electrode. In order to form the electrode 200, Ag may be deposited on the first layer 12 and the second layer 14 and then annealed. In order to minimize oxygen loss in Bi-2122 constituting the first layer 12 and the second layer 140 during the annealing process, annealing may be performed in an oxygen atmosphere. After that, Au may be overlaid on Ag, which may be to prevent oxidation of Ag.

In addition, necessary characteristics can be measured by connecting a current biasing device 300 and a voltmeter 400 to the electrode 200 for functioning as the device 500.

According to one embodiment of the present disclosure, by stacking the first layer 12 and the second layer 14 having the same element and atomic arrangement structure by being separated from one van der Waals material 10 to be layered in a twisted state, a Josephson junction can be formed from the atomic arrangement structures dislocated from each other. Through this, a new type of Josephson junction can be formed by generating a superconducting gap in the twisted structure, which can be used in various fields.

In addition, by separating two layers from one material and changing the angle between the two layers to form a Josephson junction, it is possible to control the properties of the Josephson junction through angle control.

In addition, according to the method for fabricating the Josephson junction structure according to an embodiment of the present disclosure, mechanical and chemical defects occurring in the process of forming the Josephson junction can be minimized to prevent deterioration of the device due to the Josephson junction.

Although representative embodiments of the present disclosure have been described in detail, a person skilled in the art to which the present disclosure pertains will understand that various modifications may be made thereto within the limits that do not depart from the scope of the present disclosure. Therefore, the scope of rights of the present disclosure should not be limited to the described embodiments, but should be defined not only by claims set forth below but also by equivalents to the claims.

What is claimed is:

1. A van der Waals stacked Josephson junction structure comprising:
a substrate;
a first layer of a van der Waals material separable into layers and positioned on the substrate; and
a second layer of the van der Waals material positioned on the first layer, wherein
the first layer and the second layer are twisted at a predetermined angle with each other, and
a Josephson junction is formed between the first layer and the second layer.

2. The van der Waals stacked Josephson junction structure of claim 1, wherein
each of the first layer and the second layer includes a superconducting layer.

3. The van der Waals stacked Josephson junction structure of claim 1, wherein
a crystal structure of the first layer and a crystal structure of the second layer are twisted at the predetermined angle.

4. The van der Waals stacked Josephson junction structure of claim 1, wherein
the van der Waals material is a superconductor selected from Bi-2212, NbSe₂, FeSe, and FeTe.

5. The van der Waals stacked Josephson junction structure of claim 1, wherein
each of the first layer and the second layer may include CuO₂.

6. A method for fabricating a van der Waals stacked Josephson junction structure, comprising:
disposing a Van der Waals material separable into layers on a substrate;
separating the van der Waals material into a first layer remaining on the substrate and a second layer separated from the first layer using a separation tool;
twisting the first layer and the second layer at a predetermined angle with each other, and
stacking the second layer on the first layer in a state of being twisted at the predetermined angle.

7. The method of claim 6, wherein
the substrate is rotated in order to twist the first layer and the second layer at the predetermined angle.

8. The method of claim 6, wherein
each of the first layer and the second layer includes a superconducting layer.

9. The method of claim 6, wherein
a crystal structure of the first layer and a crystal structure of the second layer are twisted at the predetermined angle.

10. The method of claim 6, wherein
the van der Waals material is a superconductor selected from Bi-2212, NbSe₂, FeSe, and FeTe.

11. The method of claim 6, wherein
each of the first layer and the second layer includes CuO₂.
